(19) United States
(12) Patent Application Publication
(10) Pub. No.: US 2025/0285659 A1
(43) Pub. Date: Sep. 11, 2025

(54) IN-RUSH CONTROL CIRCUIT AND VOLTAGE GENERATOR INCLUDING THE SAME

(71) Applicant: Samsung Electronics Co., Ltd., Suwon-si (KR)

(72) Inventors: GYOSOO CHOO, Suwon-si (KR); TAE-HONG KWON, Suwon-si (KR); KIWHAN SONG, Suwon-si (KR)

(21) Appl. No.: 19/019,888

(22) Filed: Jan. 14, 2025

(30) Foreign Application Priority Data
Mar. 5, 2024 (KR) 10-2024-0031550

(51) Int. Cl. G11C 5/14

(52) U.S. Cl. CPC G11C 5/148

(57) ABSTRACT

A semiconductor device includes a low-dropout (LDO) regulator, configured to generate an internal voltage using an external voltage, and an in-rush control circuit connected to the LDO regulator and configured to short-circuit the external voltage and the internal voltage to each other during a power-up period. The power generator may short-circuit the external voltage and the internal voltage to each other to prevent in-rush current.

### CROSS-REFERENCE TO RELATED APPLICATION(S)

This U.S. non-provisional application claims priority under 35 USC § 119 to Korean Patent Application No. 10-2024-0031550, filed on Mar. 5, 2024, in the Korean Intellectual Property Office, the disclosure of which is herein incorporated by reference in its entirety.

### BACKGROUND

Example embodiments relate to an in-rush control circuit and a semiconductor device including the same.

During a power-up period in which an internal voltage generator operates initially, a rising slope of an internal voltage generated by the internal voltage generator is generally smaller than a rising slope of an external voltage due to a capacitor at an output terminal. Therefore, a controller may generally attempt to charge the capacitor with large current, resulting in generation of an undesirably large amount of current flow (in-rush current) during an initial transient period, also known as a power-up period, as viewed from an external perspective. Such in-rush current may adversely affect the operation of peripheral circuits as well as the reliability of the internal voltage generator in a semiconductor device.

### SUMMARY

Example embodiments provide a semiconductor device for preventing generation of in-rush current during a power-up period.

According to an example embodiment, a semiconductor device includes a low-dropout (LDO) regulator configured to control an internal voltage using an external voltage, and an in-rush control circuit connected to the LDO regulator and configured to short-circuit the external voltage and the internal voltage to each other during a power-up period.

According to an example embodiment, a semiconductor device includes a logic circuit, a first voltage detector configured to generate a first power-up signal based on a result of monitoring an external voltage, a second voltage detector configured to generate a second power-up signal based on a result of monitoring an internal voltage, and an output driver controller turned on or turned off in response to the first power-up signal and connected between a gate of an output driver of a low-dropout (LDO) regulator and a ground voltage. The logic circuit is configured to be turned on in response to the second power-up signal.

According to an example embodiment, a memory device includes a memory cell array comprising a plurality of memory cells, and a peripheral circuit connected to the memory cell array. The peripheral circuit comprises a low-dropout (LDO) regulator configured to control an internal voltage using an external voltage, and a controller connected to the LDO regulator and configured to short-circuit the external voltage and the internal voltage to each other during a power-up period.

### BRIEF DESCRIPTION OF DRAWINGS

FIG. 1 is a block diagram of a semiconductor device according to an example embodiment.

FIGS. 2A to 3B are diagrams provided to describe the operation of the semiconductor device of FIG. 1 in more detail.

FIGS. 4 and 5 are diagrams illustrating examples of a semiconductor device according to an example embodiment.

FIG. 6 is a diagram illustrating an example of the semiconductor device according to an example embodiment.

FIGS. 7 to 8 are diagrams provided to describe examples of the semiconductor device according to an example embodiment.

FIGS. 9 to 11 are diagrams illustrating examples of a memory device according to an example embodiment.

FIG. 12 is a cross-sectional view illustrating an example of a nonvolatile memory device according to an example embodiment.

### DETAILED DESCRIPTION

Hereinafter, example embodiments will be described with reference to the accompanying drawings.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a part of the specification or in a particular claim) may be described elsewhere with a different ordinal number (e.g., “second” in another part of the specification or another claim).

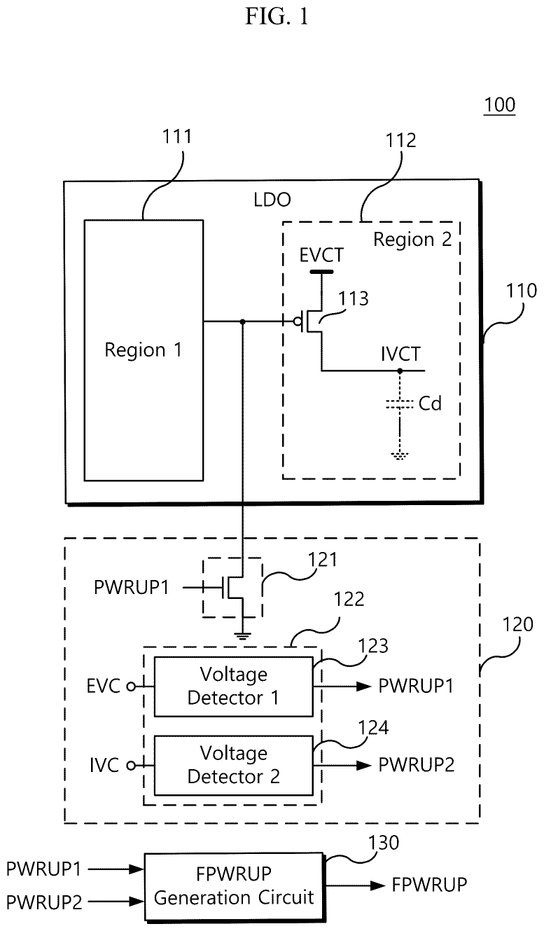

FIG. 1 is a block diagram of a semiconductor device 100 according to an example embodiment.

According to an example embodiment, the semiconductor device 100 may forcibly turn on an output driver of a low-dropout regulator (hereinafter referred to as an “LDO regulator”) by using a first power-up signal PWRUP1 to short-circuit an external voltage EVC and an internal voltage IVC. According to an example embedment, the semiconductor device 100 may include an LDO regulator”) 110, an in-rush control circuit (also referred to as an in-rush controller) 120, and a final power-up signal generation circuit (also referred to as a final power-up signal generator) 130. During a power-up period, an output driver 113 of the LDO regulator 110 may be forcibly turned on by using a first power-up signal PWRUP1 to short-circuit an external voltage EVC and an internal voltage IVC (i.e., the external voltage EVC and the internal voltage IVC are electrically connected). Generally, an LDO regulator is not unused (or operated) during a power-up period. The external voltage EVC and the internal voltage IVC may serve as voltage levels of source power for operating a semiconductor device. From an external voltage source, the external voltage EVC may be received by the output driver 113 through an external voltage terminal EVCT, and may be transferred to the internal voltage terminal IVCT by the output driver 113.

Accordingly, a capacitor Cd in an output region of the LDO regulator 110 may be rapidly charged, and a rising slope of the internal voltage IVC may become equal to a rising slope of the external voltage EVC. As a result, in-rush current may be prevented during the power-up period (or initial transient period).

The LDO regulator 110 may receive the external voltage EVC as an input voltage and control the internal voltage IVC as an output voltage. The LDO regulator 110 may be connected to (or be a part of) various load blocks, such as a central processing unit, a page buffer, or an input/output circuit, and may control the internal voltage IVC required by a corresponding load block. For example, the internal voltages may be defined (or configured) to have various levels depending on types of load blocks. For example, an internal voltage may be set to have a first level of a first internal power supply voltage used for a page buffer. For example, a second internal voltage may be set to have a second level of a second internal power supply voltage used for a data path. The first level and the second level may be different from each other. In addition, other internal voltages may be set to various levels as other internal power supply voltages.

The LDO regulator 110 may include a first region 111 and a second region 112.

The first region 111 may refer to a region, other than the second region 112, in the LDO regulator 110. For example, the first region 111 may include a circuit comparing the internal voltage IVC with a voltage level of a reference voltage. However, this is merely an example, and the first region 111 may be implemented in various ways.

The second region 112 may include the output driver 113, and the output driver 113 may electrically connect or disconnect the external voltage terminal EVCT and the internal voltage terminal IVCT. The output driver 113 may be implemented as, for example, a PMOS transistor. However, this is merely an example, and the output driver 113 may also be implemented with an NMOS transistor, or another transistor or switch. The second region 112 may be referred to as the output region of the LDO regulator 110.

The LDO regulator 110 may not operate during at least a portion of the power-up period. For example, the LDO regulator 110 may not operate during a power-up period in which the external voltage EVC and internal voltage IVC rise to an appropriate voltage level immediately after power-on. The LDO regulator 110 may perform an operation of controlling the internal voltage IVC stable after the power-up period. For example, as will be described below, during the power-up period in which the entire part of the LDO regulator 110 is not operating, but the output driver 113 of the LDO regulator 110 may be forcibly turned on, and thus the external voltage EVC and internal voltage IVC may be short-circuited to each other

The in-rush control circuit 120 may monitor the external voltage EVC and control the output driver 113 (e.g., turn on the transistor) to short-circuit the external voltage EVC and internal voltage IVC to each other in the second region 112 of the LDO regulator 110 during the power-up period. The in-rush control circuit 120 may include an output driver controller 121 and a voltage detector 122, and the voltage detector 122 may include a first voltage detector 123 and a second voltage detector 124.

The output driver controller 121 may be electrically connected to a gate of the output driver 113 (e.g., a gate of a PMOS transistor) in the second region 112 of the LDO regulator 110. For example, the output driver controller 121 may be implemented as an NMOS transistor, and may have one end (e.g., a source/drain of a PMOS transistor) connected to the gate of the output driver 113 and the other end (e.g., another source/drain of a PMOS transistor) connected to a ground voltage. However, this is merely an example, and the output driver controller 121 may also be implemented as a PMOS transistor according to example embodiments.

The output driver controller 121 may turn on or turn off the output driver 113 based on a first power-up signal PWRUP1. For example, the first power-up signal PWRUP1 may be high (i.e., at a high level) during the power-up period, and then the output driver controller 121 may be turned on in response to the first power-up signal PWRUP1. The gate of the output driver 113 may be connected to the external voltage EVC. Accordingly, the output driver 113 may be forcibly turned on and the external voltage EVC and internal voltage IVC may be forcibly short-circuited to each other. For example, following the power-up period, the first power-up signal PWRUP1 may be low (i.e., at a low level), and the output driver controller 121 may be maintained in a turned-off state. As a result, the entire part of the LDO regulator 110 may operate normally.

The first voltage detector 123 may monitor the external voltage EVC. When the external voltage EVC starts to be detected due to the power-on (e.g., when the external voltage EVC reaches a predetermined level), the first voltage detector 123 may output a first power-up signal PWRUP1 that is high. Accordingly, the external voltage EVC and internal voltage IVC may be short-circuited to each other during the power-up period. Then, when the external voltage EVC reaches a certain voltage level, the first voltage detector 123 may output a first power-up signal PWRUP1 that is low. As a result, the electrical connection between the external voltage EVC and the internal voltage IVC may be interrupted in response to the external voltage EVC reaching the certain voltage level.

The second voltage detector 124 may monitor the internal voltage IVC. During the power-up period (e.g., when the internal voltage IVC reaches a predetermined level), the second voltage detector 124 may output a second power-up signal PWRUP2 that is high. Then, when the internal voltage IVC reaches a target voltage and, the electrical connection between the external voltage EVC and internal voltage IVC is interrupted, the second voltage detector 124 may output a second power-up signal PWRUP2 that is low.

The final power-up signal generation circuit 130 may receive the first power-up signal PWRUP1 and the second power-up signal PWRUP2, and generate a final power-up signal FPWRUP based on the first and second power-up signals PWRUP1 and PWRUP2. For example, the final power-up signal generation circuit 130 may generate a final power-up signal FPWRUP (i.e., a high level of final power-up signal FPWRUP) when both the first power-up signal PWRUP1 and the second power-up signal PWRUP2 are low. The final power-up signal FPWRUP may be provided to a load block such as a latch circuit.

As described above, the output driver 113 of the LDO regulator 110 may be turned on during the power-up period to short-circuit the external voltage EVC and internal voltage to each other. Accordingly, the capacitor Cd in the output region of the LDO regulator 110 may be rapidly charged, and the rising slope of the internal voltage IVC may become equal to the rising slope of the external voltage EVC. As a result, in-rush current may be prevented during the power-up period.

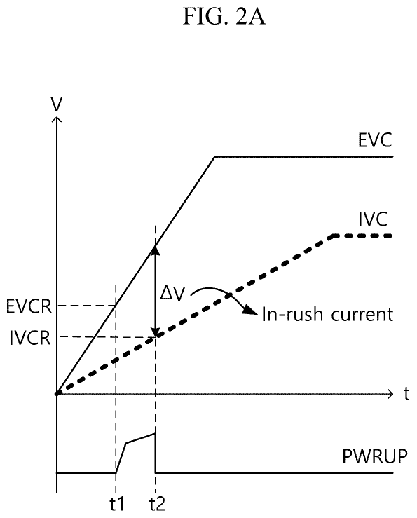

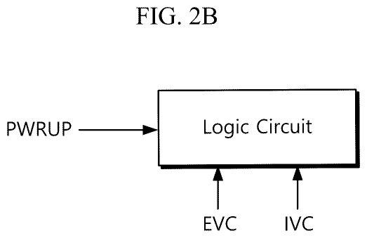

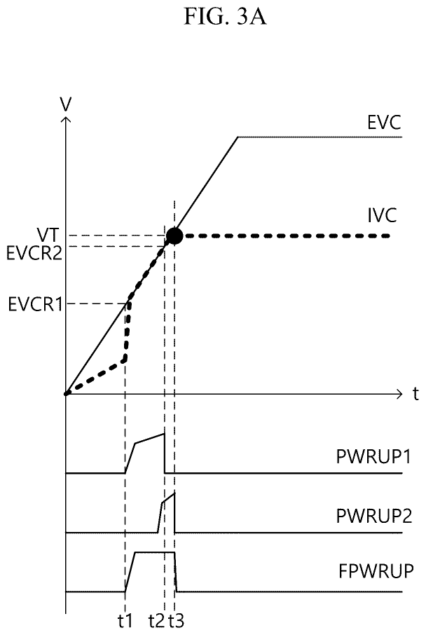

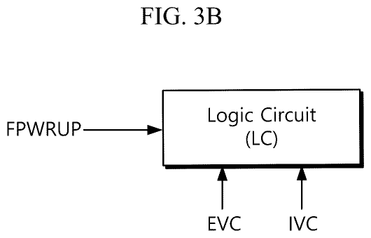

FIGS. 2A to 3B are diagrams provided to describe the operation of the voltage generator of a semiconductor device of FIG. 1 in more detail. FIG. 2A is a diagram illustrating an example of the operation of a general voltage generator during a power-up period, and FIG. 2B is a diagram illustrating an example of a logic circuit (i.e., a load block) receiving a power-up signal generated in FIG. 2A. FIG. 3A is a diagram illustrating an example of the operation of the voltage generator of FIG. 1 during a power-up period, and FIG. 3B is a diagram illustrating an example of a logic circuit receiving a final power-up signal generated in FIG. 3A. In FIGS. 2A and 3A, the vertical axis represents the voltage level V, while the horizontal axis represents time.

Referring to FIGS. 2A and 2B, a general voltage generator controls an internal voltage IVC using an external voltage EVC. The generated internal voltage IVC is provided to a logic circuit requiring a data initialization operation, such as a data latch circuit. During a power-up, a rising slope of the internal voltage IVC is smaller than a rising slope of the external voltage EVC, which may cause in-rush current to be generated in the logic circuit.

A more detailed description is now provided. At a first time point t1, when the external voltage EVC is detected (e.g., in response to the external voltage EVC reaching an external voltage level EVCR), the general voltage generator changes the level of the power-up signal PWRUP to high. At a second time point t2, in response to the internal voltage IVC reaching an internal voltage level IVCR, the general voltage generator changes the level of the power-up signal PWRUP to low. Then, the logic circuit is powered on in response to the power-up signal PWRUP that is low, and the external voltage EVC and internal voltage IVC are provided to the logic circuit.

At the second time point t2, a voltage difference A V between the external voltage EVC and the internal voltage IVC may induce in-rush current in the logic circuit. For example, when the logic circuit is a logic circuit requiring a data initialization operation, such as a data latch, the data initialization operation may not be performed normally due to the in-rush current.

In contrast, referring to FIGS. 1, 3A, and 3B, the semiconductor device 100 according to an example embodiment may control an internal voltage IVC to have the same rising slope as an external voltage EVC during at least a portion of a power-up period. As a result, in-rush current may be prevented, and a logic circuit LC may stably perform a data initialization operation. Terms such as “same,” “equal,” etc. as used herein when referring to features such as orientation, layout, location, shapes, sizes, compositions, amounts, or other measures do not necessarily mean an exactly identical feature but is intended to encompass nearly identical features, for example, including typical variations that may occur resulting from a noise component when a voltage is measured. The term “substantially” may be used herein to emphasize this meaning.

A more detailed description is now provided. At a first time point t1, the first voltage detector 123 may detect that the external voltage EVC reaches a first external voltage level (also referred to as a first predetermined level) EVCR1, and may transition the first power-up signal PWRUP1 from a low level to a high level. Accordingly, the output driver 113 be turned on, and an external voltage terminal EVCT and an internal voltage terminal IVCT may be forcibly connected to each other in the second region 112 of the LDO regulator 110. For example, the external voltage EVC and internal voltage IVC may be short-circuited to each other, and thus a capacitor Cd in the second region 112 may be rapidly charged and the rising slope of the internal voltage IVC may become equal to the rising slope of the external voltage EVC. As a result, the internal voltage IVC and external voltage EVC may rise with the same slope.

At a second time point t2, in response to the external voltage EVC reaching a second external voltage level (also referred to as a second predetermined level) EVCR2, the first voltage detector 123 may transition the first power-up signal PWRUP1 to a low level. Accordingly, the output driver 113 may be turned off, and the electrical connection between the external voltage EVC and internal voltage IVC may be interrupted. Then, the external voltage EVC may continue to rise.

Between the first time point t1 and the second time point t2, the second voltage detector 124 may transition the second power-up signal PWRUP2 from a low level to a high level. For example, the second voltage detector 124 may detect that the internal voltage IVC rises rapidly due to the short-circuit of the external voltage EVC and internal voltage IVC, and may transition the second power-up signal PWRUP2 from a low level to a high level.

Then, in response to the internal voltage IVC reaching a target voltage VT or stops rising and stabilizes, the second voltage detector 124 may transition the second power-up signal PWRUP2 from a high level to a low level. For example, at a third time point t3, the second voltage detector 124 may transition the second power-up signal PWRUP2 from a high level to a low level. For example, the second external voltage level EVCR2 and the target voltage VT may be the same level as or a similar level to each other.

At the first time point t1, the final power-up signal generation circuit 130 may generate the final power-up signal FPWRUP having a high level. After or at the third time point t3, the final power-up signal FPWRUP may be changed based on the first power-up signal PWRUP1 and the second power-up signal PWRUP2. For example, when both the first power-up signal PWRUP1 and the second power-up signal PWRUP2 are confirmed to be low, the final power-up signal generation circuit 130 may transition the final power-up signal FPWRUP from a high level to a low level.

The final power-up signal FPWRUP transited to the low level may be provided to the logic circuit LC. The logic circuit LC may start to be driven based on the final power-up signal FPWRUP (i.e., the logic circuit LC may be turned on), and may operate using the external voltage EVC and internal voltage IVC. The voltage levels of the external voltage EVC and internal voltage IVC may be the same or may have a relatively small voltage difference) at third time point t3, so that in-rush current may not be generated in the logic circuit LC. Accordingly, the logic circuit LC may stably perform a data initialization operation, or the like.

As described above in FIGS. 1 to 3B, the semiconductor device 100 according to an example embodiment may forcibly control (e.g., turn on) the output driver 113 of the LDO regulator 110 to short-circuit the external voltage EVC and internal voltage IVC. Accordingly, the capacitor Cd in the output region of the LDO regulator 110 may be rapidly charged, and the rising slope of the internal voltage IVC may become equal to the rising slope of the external voltage EVC. As a result, in-rush current may be prevented during the power-up period.

In FIG. 1, the capacitor Cd may be a decoupling capacitor. However, it will be understood that this is merely an example and the invention is not limited thereto. According to example embodiments, the decoupling capacitor Cd may be omitted in the second region 112, and/or other capacitors (e.g., a parasitic capacitor) may be additionally provided.

In FIGS. 1 to 3B, the final power-up signal FPWRUP has been described as being provided to the logic circuit LC. However, this is merely an example and the invention is not limited thereto. In an alternative embodiment, the final power-up signal PWRUP provided to the logic circuit LC may be the same signal as the second power-up signal PWRUP2.

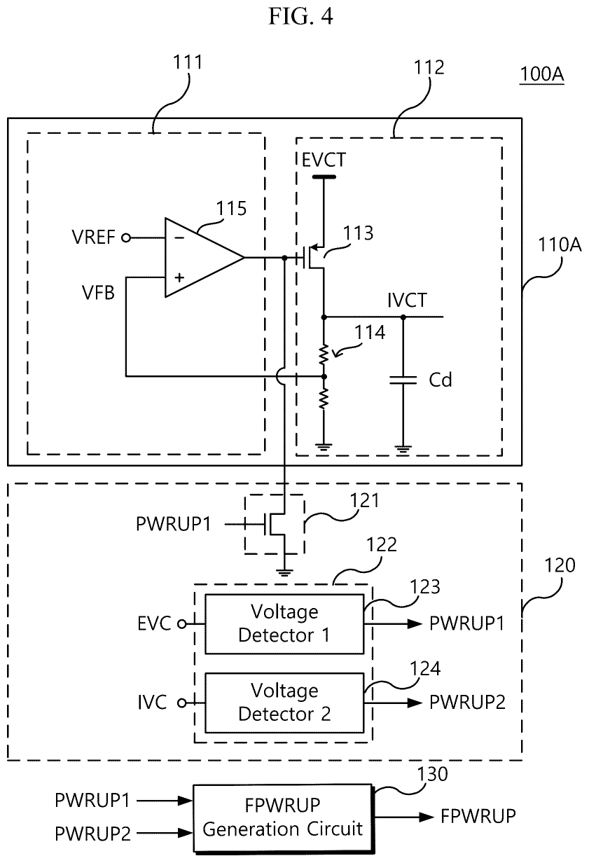

FIGS. 4 to 6 are diagrams illustrating examples of a semiconductor device according to an example embodiment. Semiconductor devices 100A, 100B, and 100C of FIGS. 4 to 6 are similar to the semiconductor device 100 of FIG. 1. Therefore, the same or similar components are denoted by the same or similar reference numerals, and redundant description will be omitted to avoid repetition.

In an example embodiment, the first region 111 of the LDO regulator 110 may be implemented in various ways.

For example, referring to FIG. 4, a semiconductor device 100A may include an LDO regulator 110A and an in-rush control circuit 120, and the LDO regulator 110 may be implemented to include a voltage divider 114, an amplifier 115, and an output driver 113. The amplifier 115 may be disposed in a first region 111, and the output driver 113 and voltage divider 114 may be disposed in a second region 112. However, this is merely an example, and the placement of the circuit elements may vary within the scope of the invention. For example, the voltage divider 114 may be disposed in the first region 111.

The voltage divider 114 may receive and divide an internal voltage IVC to generate a feedback voltage VFB. The feedback voltage VFB generated by the voltage divider 114 may be provided to an amplifier 115.

The feedback voltage VFB may be provided to a positive input terminal of the amplifier 115, and a reference voltage VREF may be provided to a negative input terminal of the amplifier 115. An output terminal of the amplifier 115 may be connected to a gate of the output driver 113.

The output driver 113 may be connected between the external voltage terminal EVCT and the voltage divider 114. The output driver 113 may form or block a channel based on a voltage level of the output terminal of the amplifier 115. For example, The output driver 113 may be a transistor, and the transistor may be turned on or off by the voltage level of the output terminal of the amplifier 115. The output terminal of the amplifier 115 may be connected to a gate of the transistor.

The operation of the LDO regulator 110A is now described in more detail. When the internal voltage IVC decreases, the feedback voltage VFB divided by the voltage divider 114 may also decrease. Accordingly, a level of the feedback voltage VFB may be lower than a level of the reference voltage VREF, and thus an output voltage of the amplifier 115 may decrease to make the channel of the output driver 113 opened (i.e., turned on), and current may be provided from an external voltage terminal EVCT to an internal voltage terminal IVCT. As described above, the LDO regulator 110A may control the internal voltage IVC stable.

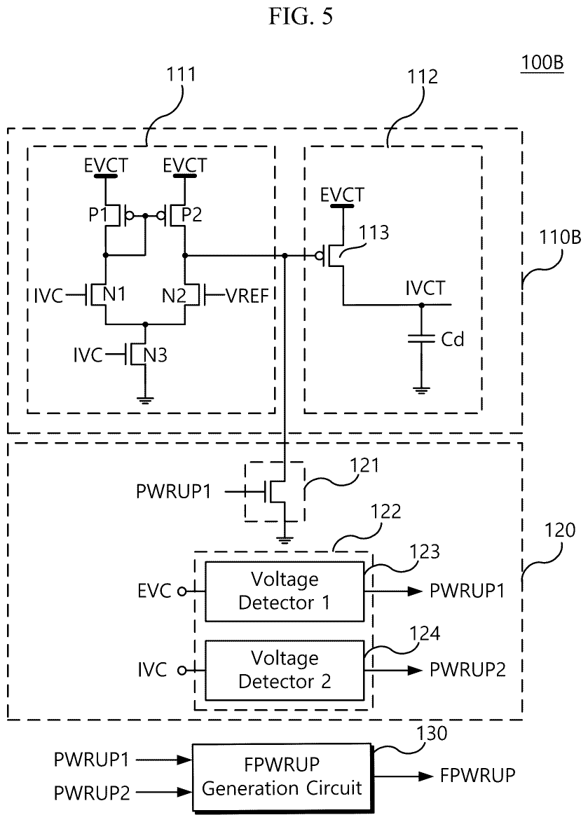

For example, referring to FIG. 5, a semiconductor device 100B may include an LDO regulator 110B and an in-rush control circuit 120, and the LDO regulator 110B may also be implemented to compare a reference voltage VREF and an internal voltage IVC.

For example, a first region 111 of the LDO regulator 110B may be implemented to include first and second PMOS transistors P1 and P2 and first to third NMOS transistors N1, N2, and N3. The first PMPS transistor P1 may have one end (i.e., source/drain) connected to an external voltage EVC (i.e., external voltage terminal EVCT), and the other end connected to a first NMOS transistor N1. The second PMOS transistor P2 may have one end connected to the external voltage EVC, and the other end connected to a second NMOS transistor N2. The first and second NMOS transistors N1 and N2 may be turned on or turned off in response to an internal voltage IVC and a reference voltage VREF, respectively. The third NMOS transistor N3 may be turned on based on the internal voltage IVC to connect one end of each of the first and second NMOS transistors N1 and N2 to a ground voltage.

According to example embodiments, during a power-up period, the entire part of the LDO regulators 110A and 110B may not operate, but the external voltage EVC and internal voltage IVC may be short-circuited to each other by an output driver 113. Accordingly, the capacitor Cd is charged at high speed, and in-rush current caused by the voltage difference between the internal voltage IVC and external voltage EVC may be prevented.

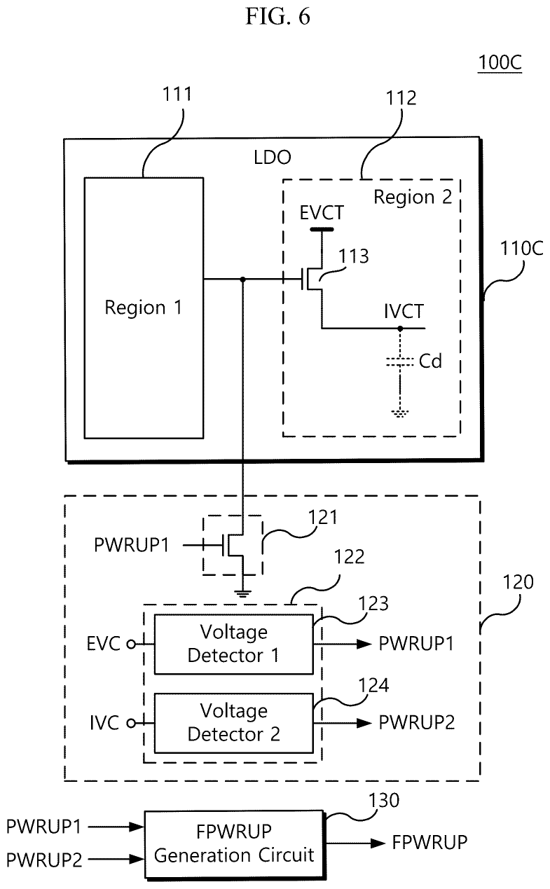

In an example embodiment, the second region 112 of the LDO regulator 110 may be implemented in various ways. For example, referring to FIG. 6, the second region 112 may include an output driver 113, and the output driver 113 may be implemented using an NMOS transistor.

In addition to the LDO regulators 110A, 110B, and 110C of FIGS. 4 to 6, an LDO regulator according to the invention may be implemented in various ways. For example, though analog LDO regulators are mainly described in FIGS. 4 to 6, this is merely examples and the invention is not limited thereto. For example, in an alternative embodiment, digital LDO regulators may be implemented, and an output driver may act to short-circuit an external voltage EVC and an internal voltage IVC. Alternatively, hybrid LDO regulators, each of which including both an analog LDO regulator and a digital LDO regulator may be implemented within the scope of the invention.

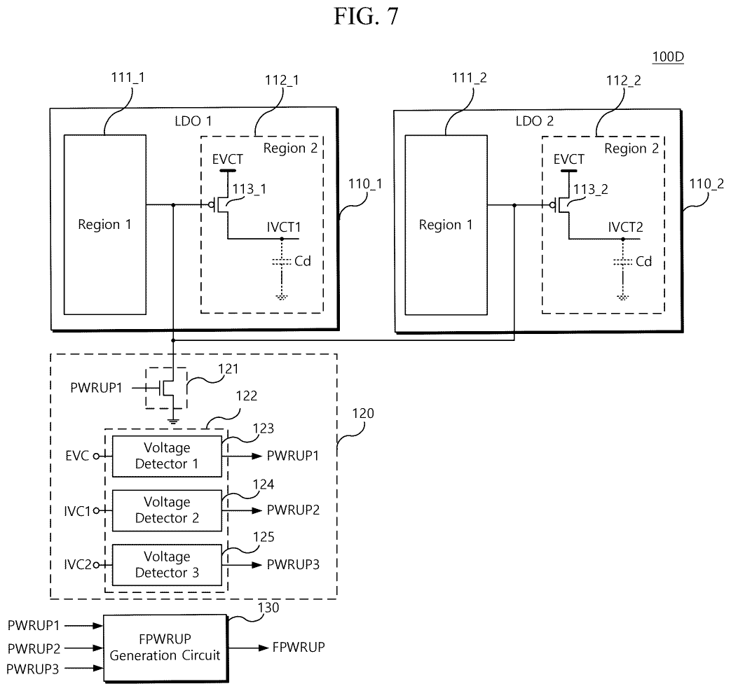

FIG. 7 is a diagram illustrating an example of a semiconductor device according to an example embodiment. A semiconductor device 100D of FIG. 7 is similar to the semiconductor device 100 of FIG. 1. Therefore, the same or similar components are denoted by the same or similar reference numerals, and redundant descriptions will be omitted to avoid repetition.

In FIGS. 1 to 6, an in-rush control circuit has been described as corresponding to a LDO regulator in a one-to-one manner. However, this is merely an example and the invention is not limited thereto. According to an example embodiment, an in-rush control circuit may correspond to a plurality of LDO regulators. For example, an in-rush control circuit may correspond to two LDO regulators, as illustrated in FIG. 7.

A more detailed description of the semiconductor device 100D is now provided with reference FIG. 7. The semiconductor device 100D may include a first LDO regulator 110_1, a second LDO regulator 110_2, an in-rush control circuit 120, and a final power-up signal generation circuit 130.

The first LDO regulator 110_1 may include a first region 111_1 and a second

region 112_1, and the second LDO regulator 110_2 may include a third region 111_2 and a fourth region 112_2.

The in-rush control circuit 120 may be commonly connected to a gate of a first output driver 113_1 of the first LDO regulator 110_1 and a gate of a second output driver 113_2 of the second LDO regulator 110_2.

A first voltage detector 123 may monitor an external voltage EVC during a power-up period. When the external voltage EVC starts to be detected, a first voltage detector 123 may output a first power-up signal PWRUP1 that is high. Accordingly, the first output driver 113_1 of the first LDO regulator 110_1 and the second output driver 113_2 of the second LDO regulator 110_2 may be turned on, respectively. Accordingly, in the power-up period, an external voltage EVC and a first internal voltage IVC1 of a first internal voltage terminal IVCT1 may be short-circuited to each other. The external voltage EVC and a second internal voltage IVC2 of a second internal voltage terminal IVCT2 also may be short-circuited to each other. The first and second internal voltages IVC1 and IVC2 may be different to each other.

Then, in response to the external voltage EVC reaching a certain voltage level, the first voltage detector 123 may output a first power-up signal PWRUP1 that is low. Accordingly, the external voltage EVC and the second internal voltage IVC2 may be disconnected by turning off the first output driver 113_1 of the first LDO regulator.

A second voltage detector 124 may monitor a first internal voltage IVC1. When the external voltage EVC and the first internal voltage IVC1 are short-circuited to each other during the power-up period and the first internal voltage IVC1 rises rapidly, the second voltage detector 124 may output a second power-up signal PWRUP2 that is high. Then, in response to the first internal voltage IVC1 reaching a first target voltage or stabilizing, the second voltage detector 124 may output a second power-up signal PWRUP2 that is low.

A third voltage detector 125 may monitor the second internal voltage IVC2. When the external voltage EVC and the second internal voltage IVC2 are short-circuited to each other during the power-up period and the second internal voltage IVC2 rises rapidly, the third voltage detector 125 may output a third power-up signal PWRUP3 that is high. Then, in response to the second internal voltage IVC2 reaching a second target voltage or stabilizing, the third voltage detector 125 may output a third power-up signal PWRUP3 that is low.

A final power-up signal generation circuit 130 may receive the first, second, and third power-up signals PWRUP1, PWRUP2, and PWRUP3, and output the final power-up signal FPWRUP based on the first, second, and third power-up signals PWRUP1, PWRUP2, and PWRUP3. For example, when the first, second, and third power-up signals PWRUP1, PWRUP2, PWRUP3 all transition (i.e. are changed) to a low level, the final power-up signal generation circuit 130 may output a final power-up signal FPWRUP that is high. The final power-up signal FPWRUP that is high may be provided to a circuit requiring a data initialization operation, such as a data latch circuit. In an alternative embodiment, the final power-up signal FPWRUP that is high may be provided to two different circuits, such as a first data latch circuit and a first data latch circuit. In this case, the first and second internal voltages IVC1 and IVC2 may be provided to the first data latch circuit and a first data latch circuit, respectively.

As described above, according to example embodiments, a semiconductor device may be implemented such that an in-rush control circuit corresponds to a plurality of LDO regulators.

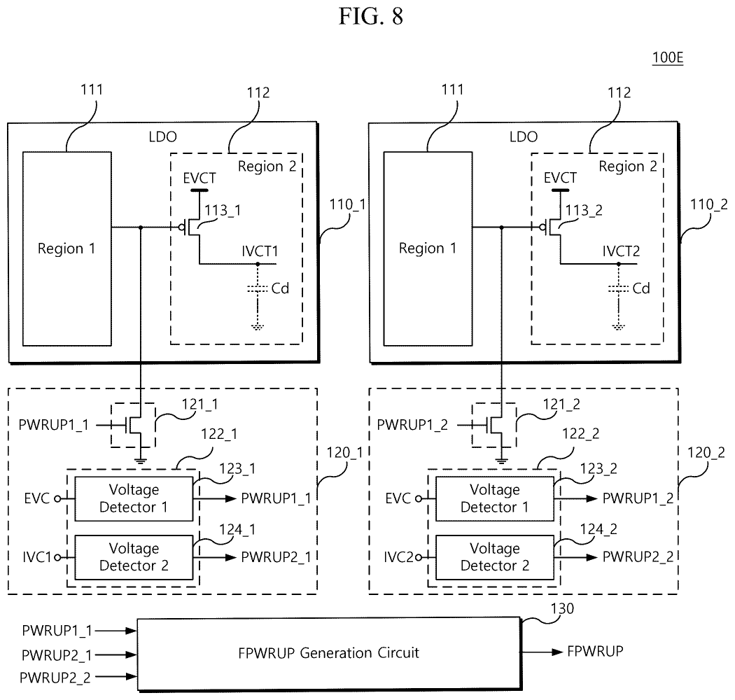

FIG. 8 is a diagram illustrating an example of a semiconductor device according to an example embodiment. A semiconductor device 100E of FIG. 8 is similar to the semiconductor device 100D of FIG. 7. Therefore, the same or similar components are denoted by the same or similar reference numerals, and redundant descriptions will be omitted to avoid repetition.

In FIGS. 1 to 8, a power-up signal generation circuit in-rush has been described as corresponding to an in-rush control circuit. However, this is merely an example and the invention is not limited thereto. For example, a semiconductor device 100E according to an example embodiment may be implemented such that a power-up signal generation circuit in-rush may correspond to a plurality of in-rush control circuits, as illustrated in FIG. 8.

A more detailed description is now provided with reference to FIG. 8. The semiconductor device 100E may include a first LDO regulator 110_1, a first in-rush control circuit 120_1, a second LDO regulator 110_2, a second in-rush control circuit 120_2, and a final power-up signal generation circuit 130.

A first in-rush control circuit 120_1 may correspond to the first LDO regulator 110_1. For example, a first voltage detector 123_1 may monitor an external voltage EVC and output a first power-up signal PWRUP1_1. During a power-up period, a first output driver 113_1 may be forcibly turned on based on the first power-up signal PWRUP1_1, and thus the external voltage EVC and a first internal voltage IVC1 may be short-circuited. The second voltage detector 124_1 may monitor the first internal voltage IVC1 and output a second power-up signal PWRUP2_1.

A second in-rush control circuit 120_2 may correspond to the second LDO regulator 110_2. For example, a third voltage detector 123_2 may monitor the external voltage EVC and output a third power-up signal PWRUP1_2. During a power-up period, a second output driver 113_2 may be forcibly turned on based on the third power-up signal PWRUP1_2, and thus the external voltage EVC and a second internal voltage IVC2 may be short-circuited. A fourth voltage detector 124_2 may monitor the second internal voltage IVC2 and output a fourth power-up signal PWRUP2_1.

A final power-up signal generation circuit 130 may receive at least one of the first power-up signal PWRUP1_1 and the third h power-up signal PWRUP1_2, and the second and fourth power-up signals PWRUP2_1 and PWRUP2_2. The final power-up signal generation circuit 130 may output a final power-up signal FPWRUP based on the received power-up signals. For example, the final power-up signal generation circuit 130 may receive the first, second and fourth power-up signals PWRUP1_1, PWRUP2_1, and PWRUP2_2, and output a final power-up signal FPWRUP based on the selected power-up signals.

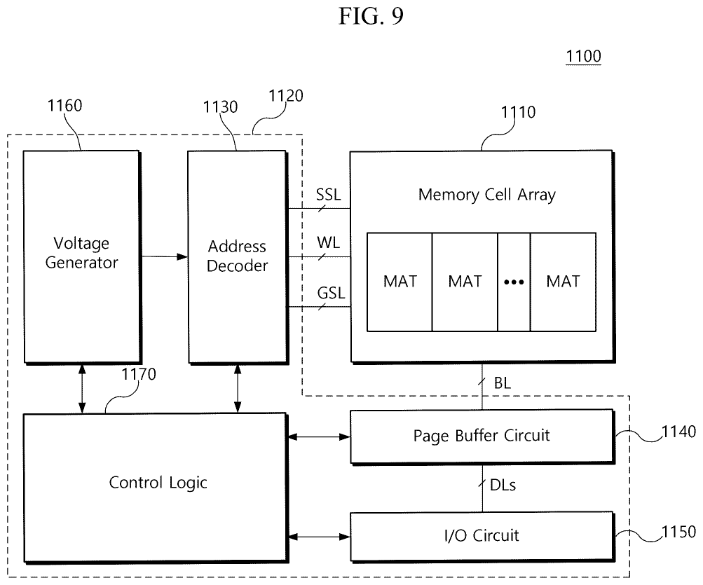

FIG. 9 is a diagram illustrating an example of a memory device according to an example embodiment.

A memory device 1100 may include a memory cell array 1110 and a peripheral circuit 1120, and the peripheral circuit 1120 may include an address decoder 1130, a page buffer circuit 1140, a data input/output circuit 1150, a voltage generator 1160, and a control logic 1170.

The memory cell array 1110 may include a plurality of mats MAT, and each of the plurality of mats MAT may include a plurality of memory blocks. Each of the plurality of memory blocks may have a 2-dimensional structure or a 3-dimensional structure. In a memory block having a 2-dimensional structure (or a horizontal structure), memory cells may be formed in a direction, parallel to a substrate. In a memory block having a 3-dimensional structure (or a vertical structure), memory cells may be formed in a direction, vertical to substrate. Multi-bit data may be stored in each of the memory cells.

The address decoder 1130 may be connected to the memory cell array 1110 through row lines. The row lines may include select lines, such as string select lines SSL or ground select lines GSL, and wordlines WL. According to an example embodiment, the row lines may further include dummy wordlines Dummy WL disposed adjacent to the select lines. When the memory cell array 1110 has a multi-stack structure in which two or more stacks are stacked, the row lines may further include dummy wordlines connected to dummy cells disposed on a bonding portion of the multi-stack structure.

The address decoder 1130 may select one of the plurality of memory blocks under the control of the control logic 1170. In addition, the address decoder 1130 may select one of the wordlines WLs during a program operation.

The page buffer circuit 1140 may be connected to the memory cell array 1110 through column lines. A column line may include, for example, a bitline BL. The page buffer circuit 1140 may temporarily store data to be programmed in a selected page or data read from the selected page.

The data input/output circuit 1150 may be connected to the page buffer circuit 1140 through data lines DLs internally, and may be connected to the memory controller 1200 through input/output lines externally. The data input/output circuit 1150 may receive data to be programmed in a selected memory cell of the memory cell array 1110 from the memory controller 1200 during a program operation and may provide data, read from the selected memory cell, to the memory controller during a read operation.

The voltage generator 1160 may generate a row line voltage required to read or write data. The row line voltage may be provided to a string select line SSL, a wordline WL, and/or a ground select line GSL through the address decoder 1130.

The control logic 1170 may control the overall operation of the memory device 1100 in response to a command CMD and an address ADDR provided from the memory controller 1200.

In an example embodiment, the voltage generator 1160 may be or include at least a part of the elements illustrated in FIGS. 1 to 8. For example, the voltage generator 1160 may include an LDO regulator and an in-rush control circuit connected to the LDO regulator. The LDO regulator does not operate during a power-up period, and the in-rush control circuit may short-circuit an external voltage and an internal voltage during the power-up period. Accordingly, generation of in-rush current caused by a difference between the internal voltage and the external voltage may be prevented.

The LDO regulator and the in-rush control circuit according to an example embodiment may be implemented for each mat MAT. Alternatively, the LDO regulator and in-rush control circuit according to an example embodiment may be implemented for each internal voltage used in the memory device 1100. For example, the LDO regulator and in-rush control circuit according to an example embodiment may be implemented to control an internal voltage used in one of the address decoder 1130, the page buffer circuit 1140, and the data input/output circuit 1150. The in-rush control circuit may prevent in-rush current by short-circuiting the external voltage and the internal voltage during the power-up period.

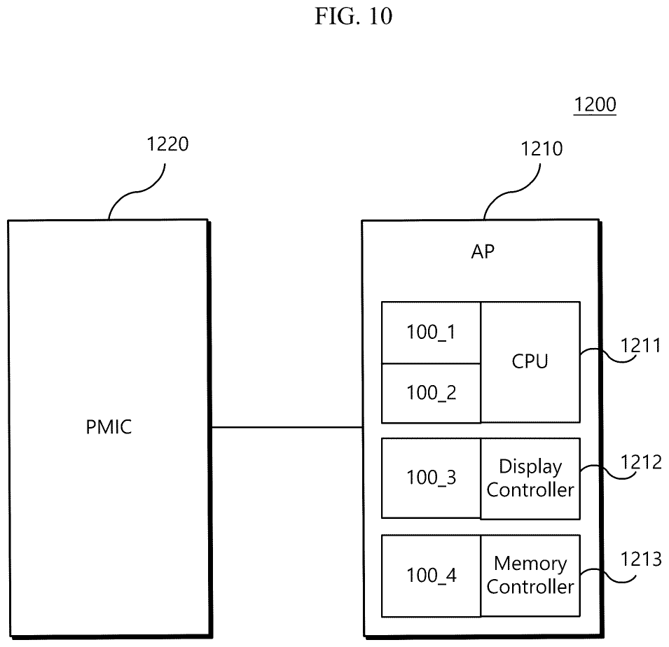

FIG. 10 is a block diagram illustrating an example of a user device according to an example embodiment.

Referring to FIG. 10, a user device 1200 may include a power management integrated circuit (PMIC) 1220 and a semiconductor device, which may be an application processor 1210.

The application processor 1210 may be connected to the power management integrated circuit 1220 through a power line. For example, an external voltage of 1.8 V may be provided through the power line. The application processor 1210 may receive an external voltage from the power management integrated circuit 1220, and may internally generate internal voltages having various levels (for example, 0.8 V, 0.9 V, 1.1 V, or the like).

To this end, the application processor 1210 may include first to fourth voltage generators 100_1 to 100_4. For example, the first voltage generator 100_1 may receive an external voltage of 1.8 V and generate an internal voltage of 0.9 V. The second voltage generator 100_2 may generate an internal voltage of 0.8 V. The internal voltages of the first and second voltage generators 100_1 and 100_2 may be provided to a central processing unit 1211. The third voltage generator 100_3 may generate an internal voltage of 1.1 V and provide the generated internal voltage to a display controller 1212. The fourth voltage generator 100_4 may generate an internal voltage of 0.8 V and provide the generated internal voltage to a memory controller 1213. However, this configuration is merely an example, and the application processor 1210 may include various internal circuits or internal chips and may include a corresponding number of voltage generators.

In an example embodiment, at least one of the plurality of voltage generators 100_1 to 100_4 may be or include at least a part of the elements illustrated in FIGS. 1 to 8. For example, at least one of the plurality of voltage generators 100_1 to 100_4 may include an LDO regulator and an in-rush control circuit, and the in-rush control circuit may prevent in-rush current by short-circuiting an external voltage and an internal voltage of during a power-up period.

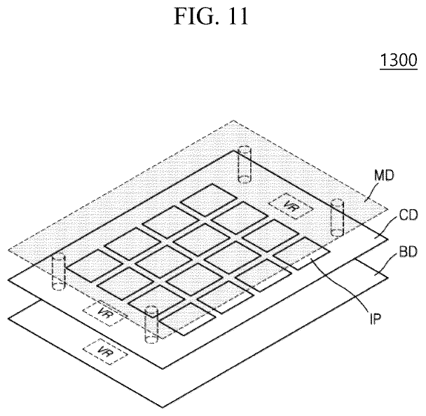

FIG. 11 is a diagram illustrating a chiplet structure according to an example embodiment. For example, a 3D chiplet structure is illustrated in FIG. 11.

Referring to FIG. 11, a memory system 1300 may have a 3-dimensional (3D) chiplet structure including a plurality of semiconductor devices such as a base die BD and a compute die CD stacked on the base die BD. A plurality of intellectual properties (IP) may be disposed on at least one of the base die BD and the compute die CD. In FIG. 11, the plurality of intellectual properties (IP) are illustrated as being disposed on the compute die CD. However, the invention is not limited thereto, and a plurality of intellectual properties (IP) may also be disposed on the base die BD.

Each of the plurality of intellectual properties (IP) may be a chip designed to perform a specific function. For example, each of the plurality of intellectual properties (IP) may be a central processing unit (CPU) chip, an input/output interface chip, a chip in which circuits for operations of artificial intelligence (AI) are implemented, a graphics chip, or a media chip. A portion of the plurality of intellectual properties (IP) may be chips configured to perform the same function. The type of plurality of intellectual properties (IP), disposed on the base die BD and the compute die CD, may vary depending on the purpose of the memory system 1300.

The memory system 1300 may include a voltage regulator VR, and the voltage regulator VR may be disposed on at least one of the plurality of dies included in the memory system 1300, for example, one of the base die BD and compute die CD. The plurality of intellectual properties (IP) of the memory system 1300 may receive an output voltage from the voltage regulator VR. Alternatively, in an exemplary embodiment, the voltage regulator VR may be disposed outside the memory system 1300, and the memory system 1300 may receive a voltage from the voltage regulator VR.

A memory die MD may be disposed on the compute die CD of the memory system 1300. The memory die MD may be electrically connected to the memory system 1300 through an interconnect via, and the interconnection via may constitute a signal path.

In an example embodiment, the voltage regulator VR may be or include at least a part of the elements illustrated in FIGS. 1 to 8. For example, the voltage regulator VR may include an LDO regulator and an in-rush control circuit, and the in-rush control circuit may prevent in-rush current by short-circuiting an external voltage and an internal voltage during a power-up period.

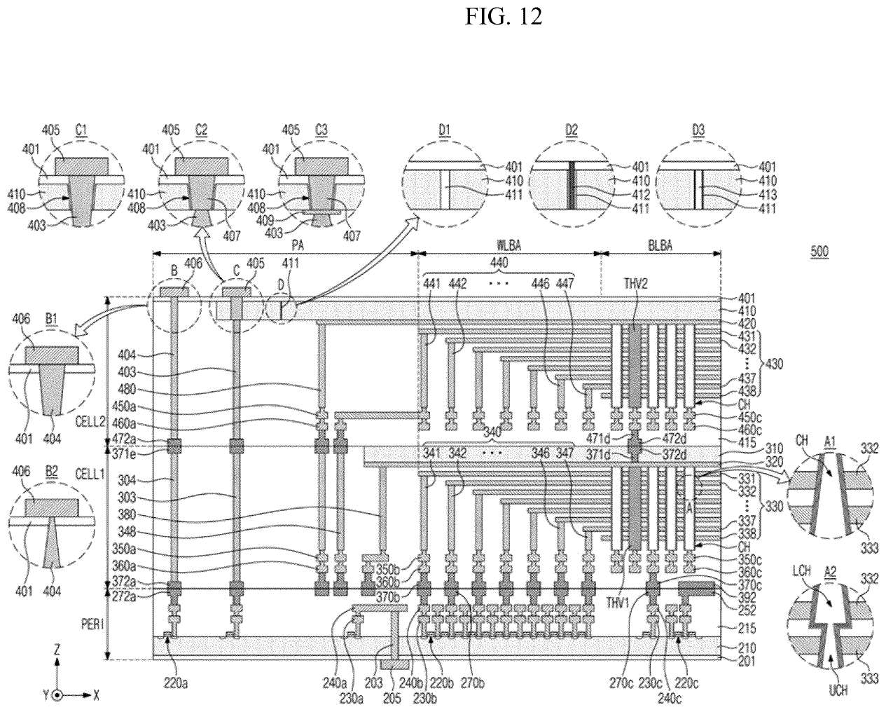

FIG. 12 is a cross-sectional view illustrating an example of a semiconductor device, which may be a nonvolatile memory device 500 according to an example embodiment. FIG. 12 may illustrate, for example, an example of the memory device 1100 of FIG. 9.

Referring to FIG. 12, the nonvolatile memory device 500 may be implemented to include two upper chips. The nonvolatile memory device 500 may be manufactured by manufacturing a first upper chip including a first cell region CELL1, a second upper chip including a second cell region CELL2, and a lower chip including a peripheral circuit region PERI, and then bonding the first upper chip, the second upper chip, and the lower chip to each other. The first upper chip may be flipped and connected to the lower chip in a bonding manner, and the second upper chip may also be flipped and connected to the first upper chip in a bonding manner.

Each of the first and second cell regions CELL1 and CELL2 may include at least one memory block. The first cell region CELL1 may include a common source line CSL in the form of a plate extending in an X-axis direction and a Y-axis direction. The common source line CSL may include a metal material, for example, tungsten (W), aluminum (Al), copper (Cu), tungsten nitride (WN), tantalum nitride (TaN), titanium nitride (TiN), or combinations thereof.

A plurality of wordlines 330 (331 to 338) may be stacked on an upper surface of the common source line CSL in a Z-axis direction. String select lines and ground select lines may be disposed above and below the plurality of wordlines 330, and the plurality of wordlines 330 may be disposed between the string select lines and the ground select lines.

Similarly, the second cell region CELL2 may include a common source line CSL, and a plurality of wordlines 430 (431 to 438) may be stacked in the Z-axis direction. A plurality of channel structures CH may be formed in each of the first and second cell regions CELL1 and CELL2. In an example embodiment, as illustrated in A1, the channel structure CH may be provided in a bitline bonding region BLBA and extend in the Z-axis direction to penetrate through the wordlines 330, the string select lines, and the ground select lines. The channel structure CH may include a data storage layer, a channel layer, and a buried insulating layer. The channel layer may be electrically connected to a first metal line 350c and a second metal line (or bitline) 360c in the bitline bonding region BLBA. For example, the second metal line 360c may be a bitline and may be connected to the channel structure CH through the first metal line 350c. The bitline 360c may extend in the first direction Y-axis direction, parallel to an upper surface of the second substrate 310.

In an example embodiment, as illustrated in A2, the channel structure CH may also include interconnected lower channels LCH and upper channels UCH. For example, the channel structure CH may be formed by a process for the lower channel LCH and a process for the upper channel UCH. The lower channel LCH extends in the Z-axis direction to penetrate the common source line 320 and lower wordlines 331, 332. The lower channel LCH may include a data storage layer, a channel layer, and a buried insulating layer, and may be connected to the upper channel UCH. The upper channel UCH may penetrate through the upper wordlines 333 to 338. The upper channel UCH may include a data storage layer, a channel layer, and a buried insulating layer, and the channel layer of the upper channel UCH may be electrically connected to the first metal line 350c and the second metal line 360c. As a channel length increases, it may become difficult to form a channel with a constant width due to process reasons. The nonvolatile memory device 500 according to an example embodiment may include a channel having improved width uniformity through lower channels LCH and upper channels UCH formed by sequential processes.

When the channel structure CH is formed to include the lower channel LCH and the upper channel UCH as illustrated in A2, a wordline disposed near a boundary of the lower channel LCH and the upper channel UCH may be a dummy wordline. For example, the wordline 332 and the wordline 333 forming the boundary of the lower channel LCH and the upper channel UCH may be dummy wordlines. Data may not be stored in memory cells connected to the dummy wordline. Alternatively, the number of pages corresponding to the memory cells connected to the dummy wordline may be less than the number of pages corresponding to memory cells connected to a normal wordline. A level of voltage applied to the dummy wordline may be different from a level of voltage applied to the normal wordline, which may reduce an effect that a non-uniform channel width between the lower channel LCH and the upper channel UCH has on the operation of the memory device.

In A2, the number of lower wordlines 331 and 332 penetrating through the lower channel LCH is illustrated as being less than the number of upper wordlines 333 to 338 penetrating through the upper channel UCH. However, this configuration is merely an example and the invention is not limited thereto. For example, the number of lower wordlines penetrating through the lower channel LCH may be greater than or greater than the number of upper wordlines penetrating through the upper channel UCH. In addition, a structure and a connection relationship of the channel structure disposed in the above-described first cell region CELL1 may be applied to the channel structure CH disposed in the above-described second cell region CELL2.

In the bitline bonding region BLBA, a first through-electrode THV1 may be provided in the first cell region CELL1 and a second through-electrode THV2 may be provided in the second cell region CELL2. As illustrated in FIG. 12, the first through-electrode THV1 may penetrate through the common source line CSL. The first through-electrode THV1 may include a conductive material. Alternatively, the first through-electrode THV1 may include a conductive material surrounded by an insulating material. The second through-electrode THV2 may be provided in the same form and structure as the first through-electrode THV1.

In an example embodiment, the first through-electrode THV1 and the second through-electrode THV2 may be electrically connected through the first through-metal pattern 372d and the second through-metal pattern 472d. The first through-metal pattern 372d may be formed on a lower end of the first upper chip including the first cell region CELL1, and the second through-metal pattern 472d may be formed on an upper end of the second upper chip including the second cell region CELL2. The first through-electrode THV1 may be electrically connected to the first metal line 350c and the second metal line 360c. A lower via 371d may be formed between the first through-electrode THV1 and the first through-metal pattern 372d, and an upper via 471d may be formed between the second through-electrode THV2 and the second through-metal pattern 472d. The first through-metal pattern 372d and the second through-metal pattern 472d may be connected in a bonding manner.

In a wordline bonding region WLBA, the wordlines 330 of the first cell region CELL1 may extend in the X-axis direction and may be connected to a plurality of cell contact plugs 340 (341 to 347). The first metal line 350b and the second metal line 360b may be sequentially connected to the upper portions of the cell contact plugs 340 connected to the wordlines 330. The cell contact plugs 340 may be connected to the peripheral circuit region PERI through an upper bonding metal 370b of the first cell region CELL1 and an upper bonding metal 270b of the peripheral circuit region PERI in the wordline bonding region WLBA.

In the wordline bonding region WLBA, the wordlines 430 of the second cell region CELL2 may extend in the X-axis direction and may be connected to a plurality of cell contact plugs 440 (441 to 447). The cell contact plugs 440 may be connected to the peripheral circuit region PERI through an upper metal pattern of the second cell region CELL2, a lower metal pattern and an upper metal pattern of the first cell region CELL1, and the cell contact plug 348.

In an external pad bonding region PA, a lower metal pattern 371e may be formed below the first cell region CELL1 and an upper metal pattern 472a may be formed above the second cell region CELL2. The lower metal pattern 371e of the first cell region CELL1 and the upper metal pattern 472a of the second cell region CELL2 may be connected in a bonding manner in the external pad bonding region PA. Similarly, an upper metal pattern 372a may be formed above the first cell region CELL1 and an upper metal pattern 272a may be formed above the peripheral circuit region PERI. The upper metal pattern 372a of the first cell region CELL1 and the upper metal pattern 272a of the peripheral circuit region PERI may be connected in a bonding manner.

Common source line contact plugs 380 and 480 may be disposed in the external pad bonding region PA. The common source line contact plugs 380 and 480 may be formed of a conductive material such as metal, metal compound, or doped polysilicon. The common source line contact plug 380 of the first cell region CELL1 may be electrically connected to the common source line 320, and the common source line contact plug 480 of the second cell region CELL2 may be electrically connected to the common source line 420. A first metal line 350a and a second metal line 360a may be sequentially stacked on the common source line contact plug 380 of the first cell region CELL1, and a first metal line 450a and a second metal line 460a may be sequentially stacked on the common source line contact plug 480 of the second cell region CELL2.

Input/output pads 205, 405, and 406 may be disposed in the external pad bonding region PA. Referring to FIG. 12, a lower insulating layer 201 may cover a lower surface of a first substrate 210, and a first input/output pad 205 may be formed on a lower insulating layer 201. The first input/output pad 205 may be connected to at least one of a plurality of circuit elements 220a disposed in the peripheral circuit region PERI through the first input/output contact plug 203, and may be separated from the first substrate 210 by the lower insulating layer 201. In addition, a side insulating layer may be disposed between the first input/output contact plug 203 and the first substrate 210 to electrically separate the first input/output contact plug 203 from the first substrate 210.

An upper insulating layer 401 may be formed on an upper surface of the third substrate 410 to cover the upper surface of the third substrate 410. A second input/output pad 405 and/or a third input/output pad 406 may be disposed on the upper insulating layer 401. The second input/output pad 405 may be connected to at least one of the plurality of circuit elements 220a disposed in the peripheral circuit region PERI through the second input/output contact plugs 403 and 303, and the third input/output pad 406 may be connected to at least one of the plurality of circuit elements 220a disposed in the peripheral circuit region PERI through the third input/output contact plugs 404 and 304.

In an example embodiment, the third substrate 410 may not be disposed in a region in which the input/output contact plugs are disposed. For example, as illustrated in B, the third input/output contact plug 404 may be separated from the third substrate 410 in a direction, parallel to the upper surface of the third substrate 410, and may be connected to the third input/output pad 406 through an interlayer dielectric layer 415 of the second cell region CELL2. The third input/output contact plug 404 may be formed by various processes.

For example, as illustrated in B1, the third input/output contact plug 404 may extend in a third direction (Z-axis direction) and may be formed to have a diameter increasing in a direction toward the upper insulating layer 401. For example, the channel structure CH described in A1 is formed to have a diameter decreasing in a direction toward the upper insulating layer 401, whereas the third input/output contact plug 404 may be formed to have a diameter increasing in a direction toward the upper insulating layer 401. For example, the third input/output contact plug 404 may be formed after the second cell region CELL2 and the first cell region CELL1 are coupled to each other in a bonding manner.

For example, as illustrated in B2, the third input/output contact plug 404 may extend in a third direction (Z-axis direction) and may be formed to have a diameter decreasing in a direction toward the upper insulating layer 401. For example, the third input/output contact plug 404 may be formed to have a diameter decreasing in a direction toward the upper insulating layer 401, similarly to the diameter of the channel structure CH. For example, the third input/output contact plug 404 may be formed before the second cell region CELL2 and the first cell region CELL1 are bonded to each other, along with the cell contact plugs 440.

In an example embodiment, the input/output contact plug may be disposed to overlap the third substrate 410. For example, as illustrated in C, the second input/output contact plug 403 may be formed to penetrate through the interlayer dielectric layer 415 of the second cell region CELL2 in a third direction (Z-axis direction) and may be electrically connected to the second input/output pad 405 through the third substrate 410. A connection structure between the second input/output contact plug 403 and the second input/output pad 405 may be implemented in various ways.

For example, as illustrated in C1, an opening 408 may be formed to penetrate through the third substrate 410, and the second input/output contact plug 403 may be directly connected to the second input/output pad 405 through the opening 408 formed in the third substrate 410. As illustrated in C1, the second input/output contact plug 403 may be formed to have a diameter increasing in a direction toward the second input/output pad 405. However, this configuration is merely an example, and the second input/output contact plug 403 may be formed to have a diameter decreasing in a direction toward the second input/output pad 405.

For example, as illustrated in C2, an opening 408 may be formed to penetrate through the third substrate 410, and a contact 407 may be formed within the opening 408. One end of the contact 407 may be connected to the second input/output pad 405, and the other end of the contact 407 may be connected to the second input/output contact plug 403. Accordingly, the second input/output contact plug 403 may be electrically connected to the second input/output pad 405 through the contact 407 within the opening 408. As illustrated in C2, the contact 407 may be formed to have a diameter increasing in a direction toward the second input/output pad 405 and the second input/output contact plug 403 may be formed to have a diameter decreasing in the direction toward the second input/output pad 405. For example, the third input/output contact plug 403 may be formed along with the cell contact plugs 440 before the second cell region CELL2 and the first cell region CELL1 are bonded to each other, and the contact 407 may be formed after the second cell region CELL2 and the first cell region CELL1 are bonded to each other.

For example, as illustrated in C3, a stopper 409 may be further formed on the upper surface of the opening 408 of the third substrate 410, compared to C2. The stopper 409 may be a metal line formed in the same layer as the common source line 420. However, this configuration is merely an example, and the stopper 409 may also be a metal line formed in the same layer as at least one of the wordlines 430. The second input/output contact plug 403 may be electrically connected to the second input/output pad 405 through the contact 407 and the stopper 409.

Similarly to the second and third input/output contact plugs 403 and 404 of the second cell region CELL2, second and third input/output contact plugs 303 and 304 of the first cell region CELL1 may be formed to have a diameter decreasing in a direction toward the lower metal pattern 371e or a diameter increasing in the direction toward the lower metal pattern 371e.

According to example embodiments, a slit 411 may be formed in the third substrate 410. For example, the slit 411 may be formed in any location of the external pad bonding region PA. For example, as illustrated in D, the slit 411 may be disposed between the second input/output pad 405 and the cell contact plugs 440 when viewed in a plan view. However, this configuration is merely an example, and the slit 411 may be formed such that the second input/output pad 405 is disposed between the slit 411 and the cell contact plugs 440 when viewed in a plan view.

For example, as illustrated in D1, the slit 411 may be formed to penetrate through the third substrate 410. The slit 411 may be used, for example, to prevent the third substrate 410 from cracking when the opening 408 is formed. However, this configuration is merely an example, and the slit 411 may also be formed to a depth of about 60 to 70% of a thickness of the third substrate 410.

For example, as illustrated in D2, a conductive material 412 may be formed within the slit 411. The conductive material 412 may be used, for example, to discharge leakage current, generated during driving of circuit elements in the external pad bonding region PA, to the outside. The conductive material 412 may be connected to an external ground line.

For example, as illustrated in D3, an insulating material 413 may be formed within the slit 411. The insulating material 413 may be formed, for example, to electrically isolate the second input/output pad 405 and the second input/output contact plug 403, disposed in the external pad bonding region PA, from the wordline bonding region WLBA. The insulating material 413 formed within the slit 411 may prevent a voltage, provided through the second input/output pad 405, from affecting the metal layer disposed on the third substrate 410 within the wordline bonding region WLBA.

In example embodiments, the first to third input/output pads 205, 405, and 406 may be selectively formed. For example, the memory device 500 may be implemented to include only the first input/output pad 205 disposed on the upper surface of the first substrate 210, or only the second input/output pad 405 disposed on the upper surface of the third substrate 410, or only the third input/output pad 406 disposed on the upper surface of the upper insulating layer 401.

According to example embodiments, at least one of the second substrate 310 of the first cell region CELL1 and the third substrate 410 of the second cell region CELL2 may be used as a sacrificial substrate and may be completely or partially removed before or after a bonding process. An additional layer may be stacked after the substrate removal.

For example, the second substrate 310 of the first cell region CELL1 may be removed before or after bonding of the peripheral circuit region PERI and the first cell region CELL1, and an insulating layer covering an upper surface of the common source line 320 or a conductive layer for connection of the upper surface of the common source line 320 may be formed. Similarly, the third substrate 410 of the second cell region CELL2 may be removed before or after bonding of the first cell region CELL1 and the second cell region CELL2, and an upper insulating layer 401 covering an upper surface of the common source line 420 or a conductive layer for connection of the upper surface of the common source line 420 may be formed.

In an example embodiment, the peripheral circuit region PERI may include the elements described in FIGS. 1 to 8. The semiconductor device 500 may include an LDO regulator and an in-rush control circuit, and the in-rush control circuit may prevent in-rush current by short-circuiting an external voltage and an internal voltage during a power-up period.

As set forth above, a semiconductor device according to example embodiments may prevent generation of in-rush current during a power-up period.

While example embodiments have been shown and described above, it will be apparent to those skilled in the art that modifications and variations could be made without departing from the scope of the present inventive concept as defined by the appended claims.

What is claimed is:

1. A semiconductor device comprising:
a low-dropout (LDO) regulator configured to control an internal voltage using an external voltage; and
an in-rush control circuit connected to the LDO regulator and configured to short-circuit the external voltage and the internal voltage to each other during a power-up period.

2. The semiconductor device of claim 1, wherein
the LDO regulator comprises an output driver connected between an external voltage terminal receiving the external voltage and the internal voltage, and
the in-rush control circuit comprises an output driver controller connected to the output driver and configured to control the output driver during the power-up period.

3. The semiconductor device of claim 2, further comprising a first voltage detector configured to generate a first power-up signal based on a result of monitoring the external voltage,
wherein the output driver controller is configured to control the output driver during the power-up period in response to the first power-up signal to short-circuit the external voltage and the internal voltage to each other.

4. The semiconductor device of claim 3, wherein:
the first voltage detector is configured to detect when the external voltage reaches a first predetermined level,
in response to the detection, the first voltage detector is configured to change the first power-up signal from a first level to a second level, and
in response to the first power-up signal being changed to the second level, the output driver controller is configured to control the output driver, thereby the external voltage and the internal voltage having the same rising slope as each other.

5. The semiconductor device of claim 3, wherein:
the first voltage detector is configured to detect when the external voltage reaches a second predetermined level,
in response to the detection, the first voltage detector is configured to change the first power-up signal from a first level to a second level, and
in response to the first power-up signal being changed to the second level, the output driver controller is configured to control the output driver, thereby electrically disconnecting the external voltage and the internal voltage to each other.

6. The semiconductor device of claim 3, further comprising a second voltage detector configured to generate a second power-up signal, different from the first power-up signal, based on a result of monitoring the internal voltage.

7. The semiconductor device of claim 6, further comprising a logic circuit,
wherein the second voltage detector is configured to enable the second power-up signal in response to the internal voltage reaching a target voltage level, thereby the internal voltage being provided to the logic circuit.

8. The semiconductor device of claim 7, further comprising a final power-up signal generator configured to generate a final power-up signal to be provided to the logic circuit, based on the first power-up signal and the enabled second power-up signal, wherein the internal voltage is supplied to the logic circuit in response to the final power-up signal.

9. The semiconductor device of claim 1, further comprising an additional LDO regulator configured to control an additional internal voltage, different from the internal voltage, using the external voltage, wherein the in-rush control circuit is connected to the additional LDO regulator and is configured to short-circuit the external voltage and the additional internal voltage to each other during the power-up period.

10. The semiconductor device of claim 9, wherein
the LDO regulator comprises an output driver connected between the external voltage and the internal voltage,
the additional LDO regulator comprises an additional output driver connected between the external voltage and the additional internal voltage,
the in-rush control circuit comprises an output driver controller connected to the output driver and the additional output driver, and
the output driver controller is configured to turn on the output driver and the additional output driver during the power-up period.

11. The semiconductor device of claim 10, further comprising:
a first voltage detector configured to generate a first power-up signal based on a result of monitoring the external voltage; and
a second voltage detector configured to generate a second power-up signal based on a result of monitoring the internal voltage; and
a third voltage detector configured to generate a third power-up signal based on a result of monitoring the additional internal voltage,
wherein the in-rush controller is configured to turn on the output driver and the additional output driver during the power-up period in response to both of the internal voltage and the additional internal voltage reaching a corresponding one of target voltage levels.

12. The semiconductor device of claim 1, further comprising:
an additional LDO regulator configured to control an additional internal voltage, different from the internal voltage, using the external voltage;
an additional in-rush control circuit connected to the additional LDO regulator and configured to short-circuit the external voltage and the additional internal voltage to each other during the power-up period; and
a final power-up signal generator configured to generate a final power-up signal to be provided to a logic circuit based on at least one first power-up signal generated from the in-rush control circuit and at least one first power-up signal generated from the additional in-rush control circuit.

13. The semiconductor device of claim 12, wherein
the LDO regulator comprises a first output driver connected between the external voltage and the internal voltage,
the in-rush control circuit comprises:
a first output driver controller connected to the first output driver and configured to turn on the first output driver during the power-up period;
a first voltage detector configured to generate a first power-up signal based on a result of monitoring the external voltage; and
a second voltage detector configured to generate a second power-up signal based on a result of monitoring the internal voltage, the additional LDO regulator comprises a second output driver connected between the external voltage and the additional internal voltage, the additional in-rush control circuit comprises:
a second output driver controller connected to the second output driver and configured to turn on the second output driver during the power-up period;
a third voltage detector configured to generate a third power-up signal based on a result of monitoring the external voltage; and
a fourth voltage detector configured to generate a fourth power-up signal based on a result of monitoring the additional internal voltage, and
the final power-up signal generator configured to generate the final power-up signal to be provided to the logic circuit based on the second power-up signal and the fourth power-up signal.

14. The semiconductor device of claim 13, wherein
the final power-up signal generator configured to generate the final power-up signal to be provided to the logic circuit based on the first to fourth power-up signals.

15. An in-rush control circuit comprising:
a first voltage detector configured to generate a first power-up signal based on a result of monitoring an external voltage;
a second voltage detector configured to generate a second power-up signal based on a result of monitoring an internal voltage; and
an output driver controller configured to be turned on or turned off in response to the first power-up signal and connected between a gate of an output driver of a low-dropout (LDO) regulator and a ground voltage.

16. The in-rush control circuit of claim 15, wherein
the output driver controller is configured to be turned on in response to the first power-up signal during a power-up period and control the output driver of the LDO regulator to short-circuit the external voltage and the internal voltage to each other.

17. The in-rush control circuit of claim 16, wherein
the output driver is configured such that the external voltage and the internal voltage have the same rising slope as each other during at least a portion of the power-up period.

18. The in-rush control circuit of claim 16, wherein
the first voltage detector is configured to change a voltage level of the first power-up signal in response to a voltage level of the external voltage reaching a predetermined voltage level, and
the output driver controller is configured to turn off the output driver in response to the first power-up signal that is low.

19. The in-rush control circuit of claim 16, wherein:
the second voltage detector is configured to enable the second power-up signal in response to the internal voltage reaching a target voltage level, and provides the enabled second power-up signal to the logic circuit.

20. A memory device comprising:
a memory cell array comprising a plurality of memory cells; and
a peripheral circuit connected to the memory cell array,
wherein the peripheral circuit comprises:
a low-dropout (LDO) regulator configured to control an internal voltage using an external voltage; and
a controller connected to the LDO regulator and configured to short-circuit the external voltage and the internal voltage to each other during a power-up period.
